(19) United States
(12) Patent Application Publication
(10) Pub. No.: US 2025/0059644 A1
(43) Pub. Date: Feb. 20, 2025

(54) SEMICONDUCTOR PROCESSING SYSTEM, A SEMICONDUCTOR PRECURSOR STORAGE VESSEL AND A METHOD OF FORMING A SILICON COMPRISING LAYER

(71) Applicant: ASM IP Holding B.V., Almere (NL)

(72) Inventor: Dieter Pierreux, Pepingen (BE)

(21) Appl. No.: 18/806,814

(22) Filed: Aug. 16, 2024

Related U.S. Application Data
(60) Provisional application No. 63/520,207, filed on Aug. 17, 2023.

(51) Int. Cl. C23C 16/448; C23C 16/34; C23C 16/46; H01L 21/02

(52) U.S. Cl. CPC C23C 16/448; C23C 16/345; C23C 16/46; H01L 21/0217; H01L 21/02271

(57) ABSTRACT

A semiconductor processing system and method for depositing silicon layers on a plurality of substrates and a semiconductor precursor storage vessel is disclosed. The system may have a reaction chamber constructed and arranged to receive a boat with a plurality of substrates, a heater configured to heat the reaction chamber to a process temperature, and a silicon precursor source constructed and arranged to provide to the reaction chamber a halosilane.

### CROSS-REFERENCE TO RELATED APPLICATION(S)

This application claims the benefit of U.S. Provisional Application 63/520,207 filed on Aug. 17, 2023, the entire contents of which are incorporated herein by reference.

### FIELD OF THE INVENTION

The present invention relates to the field of semiconductor processing, and more in particular to a semiconductor processing system, a semiconductor precursor storage vessel and a method of forming a silicon comprising layer on a plurality of substrates.

### BACKGROUND

The simultaneous processing of a plurality of semiconductor substrates by forming a silicon comprising layer on the plurality of substrates in a semiconductor processing system has been a productive way to manufacture integrated circuits. An important process condition to optimize the quality of the layer deposited on the substrates and the speed of the process is temperature. The semiconductor processing system therefore comprises a reaction chamber constructed and arranged to receive a boat with a plurality of substrates and a heater configured to heat the reaction chamber to a process temperature.

A silicon precursor source may be constructed and arranged to provide to the reaction chamber a halosilane to form a silicon comprising layer on the plurality of substrates. For some processes the maximum temperature may be limited because temperature sensitive layers may already be present at the substrate. The limited temperature may have a detrimental effect on the quality of the layer formed on the substrate or the speed at which the process takes place.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

According to an embodiment there may be provided a semiconductor processing system configured to form a silicon comprising layer on a plurality of substrates. The system may comprise a reaction chamber constructed and arranged to receive a boat with a plurality of substrates, a heater configured to heat the reaction chamber to a process temperature and a silicon precursor source. The silicon precursor source may be constructed and arranged to provide to the reaction chamber a halosilane. The halosilane may have a formula SiH₃₋ₙXₙ—(SiH_{2-q}X_{q})ₚ SiH₃₋ₘXₘ. N and m may be independently selected from an integer having a value from at least 0 to at most 3. P may be an integer having a value from at least 0 to at most 2. Q may be an integer having a value from at least 0 to at most 2. X may be an halogen and n+m+q may have a value of at least 1 to at most 5+q*p.

According to an embodiment a semiconductor precursor storage vessel constructed and arranged for providing a precursor to a vertical furnace is provided. The vessel may comprise a halosilane having a formula SiH₃₋ₙXₙ—(SiH_{2-q}X_{q})ₚ SiH₃₋ₘXₘ. N and m may be independently selected from an integer having a value of at least 0 to at most 3. P may be an integer having a value from at least 0 to at most 2. Q may be an integer having a value from at least 0 to at most 2. X may be a halogen and n+m+q may have a value of at least 1 to at most 5+q*p.

According to a further embodiment there is provided a method of forming a silicon comprising layer on a plurality of substrates. The method may comprise providing a boat with the plurality of substrates to a reaction chamber and providing a reaction gas comprising a halosilane to the reaction chamber to form the silicon comprising layer on the plurality of substrates. The halosilane may have a formula SiH₃₋ₙXₙ—(SiH_{2-q}X_{q})ₚ SiH₃₋ₘXₘ. N and m may be independently selected from an integer having a value of at least 0 to at most 3. P may be an integer from at least 0 to at most 2. Q may be an integer having a value from at least 0 to at most 2. X may be a halogen and n+m+q may have a value of at least 1 to at most 5+q*p.

The various embodiments of the invention may be applied separate from each other or may be combined. Embodiments of the invention will be further elucidated in the detailed description with reference to some examples shown in the figures.

### BRIEF DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a cross-sectional view of a reaction chamber of a semiconductor processing system according to an embodiment,

FIG. 2 depicts halosilanes according to an example of the invention with two silicon atoms per molecule,

FIG. 3 depicts halosilanes according to an example of the invention with three silicon atoms per molecule, and

FIG. 4 discloses schematically a valve system, a purge gas injection system, and a control system for cooperation with the semiconductor processing system of FIG. 1.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “substrate” or “wafer” may refer to any underlying material or materials that may be used, or upon which, a device, a circuit, or a film may be formed. The term “semiconductor device structure” may refer to any portion of a processed, or partially processed, semiconductor structure that is, includes, or defines at least a portion of an active or passive component of a semiconductor device to be formed on or in a semiconductor substrate.

Semiconductor substrates can be processed in batches in semiconductor processing systems such as for example vertical furnaces. An example of such processing is the deposition of layers of various materials on the substrates. Some of the process may be based on silicon precursors such as halosilane.

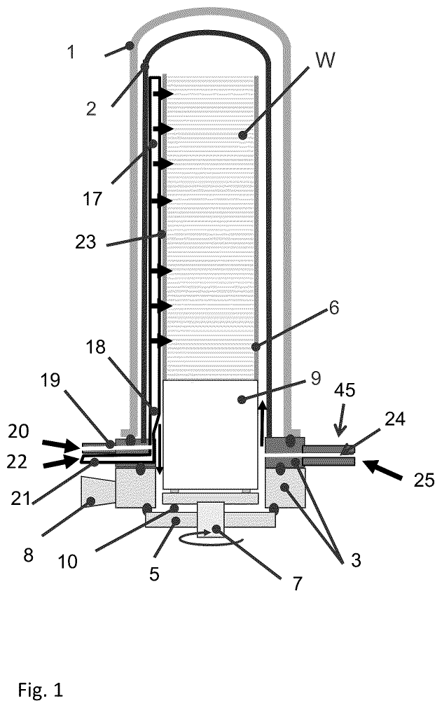

FIG. 1 is a cross sectional side view of an example of a semiconductor processing system such as a vertical furnace including a reaction chamber 1. The furnace may comprise a vertically movable door 5 configured to close off a central inlet opening 10 in flanges 3. The door 5 may be configured to support a wafer boat 6 that is configured to hold a plurality of substrates. The flanges 3 may be partially closing an open end of the reaction chamber 1. A liner 2 may extend along the reaction chamber 1 to protect the reaction chamber 1 of any deposition.

The door 5 may be provided with a drive 7 to allow for rotation of the wafer boat 6 in the reaction chamber. In between the drive 7 and the wafer boat 6 a pedestal 9 may be provided. The pedestal 9 may be provided with heaters and/or thermal insulators to improve the heat uniformity for the substrates in the boat 6.

The liner 2 may be closed at a higher end for example with a dome shape and may be substantially closed for gases above an opening at the bottom. The lower flanges 3 comprises an inlet opening 10 configured to insert and remove a boat 6 configured to carry a plurality of substrates in the reaction chamber.

A gas injector such as a multi-hole injector 17 may be provided to provide the reaction gas in the reaction chamber 1. The injector 17 may be provided inside the reaction chamber 1 extending in a substantially vertical direction over substantially a height of the wafer boat 6. The liner 2 extending along the reaction chamber 1 may have a radially outwardly extending bulge to accommodate the injector 17. The injector 17 may comprise a feed end 18 operationally connected to a first feed line 19 which may be connected to a first source of a silicon precursor 20. The feed end 18 may be operationally connected to a second feed line 21 which may be connected to a second source comprising a nitrogen precursor 22.

The silicon precursor provided at the feed end 18 of the injector 17 may comprise a halosilane. The halosilane may have the formula:

SiH₃₋ₙXₙ—(SiH_{2-q}X_{q})ₚ SiH₃₋ₘXₘ,
wherein n and m may be independently selected from an integer having a value of at least 0 to at most 3, p may be an integer from at least 0 to at most 2, q may be an integer from at least 0 to at most 2, X may be a halogen and n+m+q may have a value of at least 1 to at most 5+q*p.

The halosilane may for example be chlorine, iodine, bromine or fluorine. Adding halogens to the silicon precursor may improve the reactivity of the precursor at low temperature.

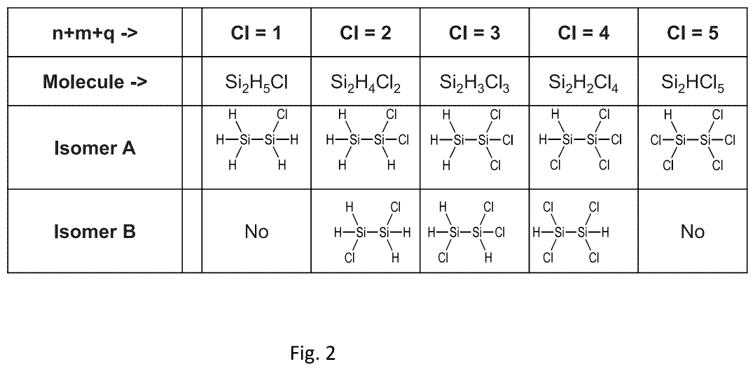

FIG. 2 depicts halosilanes according to an example of the invention with two silicon atoms per molecule. In this case p and q may be selected 0 so that we are looking at the halodisilanes. More particular chlorine may be selected for X so that we are looking at the chlorodisilanes.

Increasing the amount of chlorine (Cl) n+m+q from 1 to 5 gives the following possibilities for the molecule: chlorodisilane (Si₂H₅Cl), dichlorodisilane (Si₂H₄Cl₂), trichlorodisilane (Si₂H₃Cl₃), tetrachlorodisilane (Si₂H₂Cl₄), pentacholorodisilane (Si₂HCl₅). For n+m+q=2, 3 and 4 in the formula both isomers A and B are given as an example.

It may be advantageous to have 2 halogen atoms in the silicon precursor. In such case n+m+q in the formula may have a value of at least 2. For example, the halosilane in the silicon precursor source may comprise dichlorodisilane DCDS (Si₂Cl₂H₄).

The growth rate of DCDS at 600° C. may be 1 nm/min and at 550° C. may be 0.1 nm/min. In comparison the growth rate of DCS (SiCl₂H₂) at 600° C. may be 0.1 nm/min and at 550° C. may be 0.01 nm/min. For example, the DCDS (Si₂Cl₂H₄) used in the halosilane may be 1,1-dichlorodisilane (Isomer A of CL=2 in FIG. 2) or 1,2-dichlorodisilane (Isomer B of Cl=2 in FIG. 2).

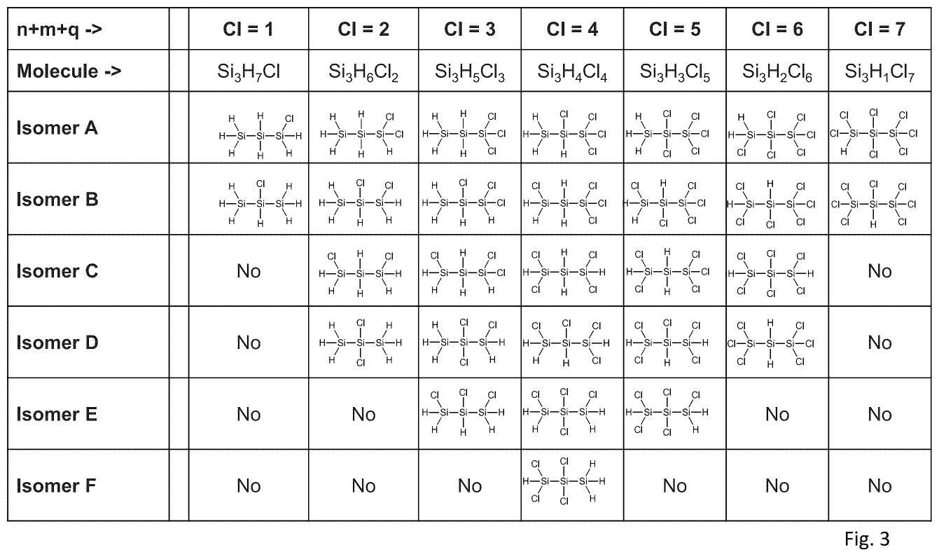

FIG. 3 depicts halosilanes according to an example of the invention with three silicon atoms per molecule. In this case p in the formula may be selected as 1 so that we are looking at the halotrisilanes. Increasing the size of the silicon precursor may improve the deposition speed of the precursor at low temperature. More particular chlorine may be selected for X in the formula so that we are looking at the chlorotrisilanes.

Increasing the amount of chlorine (Cl) n+m+q in the formula from 1 to 7 gives the following possibilities for the molecule: chlorotrisilane (Si₃H₇Cl), dichlorotrisilane (Si₃H₆Cl₃), trichlorotrisilane (Si₃H₅Cl₃), tetrachlorotrisilane (Si₃H₄Cl₄), pentacholorotrisilane (Si₃H₃Cl₅), hexachlorotrisilane (Si₃H₂Cl₆), heptachlorotrisilane (Si₃HCl7). For n+m+q=1 to 7 all isomers A to F are given as an example.

The deposited layer may be used for passivation of a Galiumnitride (GaN) layer. The halogens may leave traces in the deposited layer and therefore not more than 7 halogens in the silicon precursor may be advantageous. Also, halogens may react with hydrogen atoms to create an acid. For example, chlorine may react to hydrochloric acid which may regarded as a toxic and less environmentally friendly gas. It is therefore advantageous to minimize the halogens e.g. chlorine atoms in the silicon precursor.

The nitrogen precursor provided at the feed end 18 of the injector 17 may comprise ammonia. The nitrogen precursor and the silicon precursor e.g. halosilane may start to mix and react with each other when they enter the multi-hole injector 17 at the feed end 18.

The nitrogen precursor and the silicon precursor e.g. halosilane may be provided alternatingly to the reaction chamber. This may result in an atomic layer deposition process.

The nitrogen precursor and the silicon precursor e.g. halosilane may be provided to the reaction chamber substantially simultaneously. This may result in a chemical vapor deposition process.

The nitrogen precursor or the oxygen precursor may be mixed with the silicon precursor e.g. halosilane before being provided to the reaction chamber.

The silicon precursor e.g. halosilane may be provided, to the reaction chamber, at a flow in a range of 0.05 to 5 standard liter per minute (slm), preferably between 1 and 4 sim and most preferably about 3 slm.

The temperature of the reaction chamber during provision of the reaction gases e.g. the precursors may be less than 1000° C., less than 800° C. or even less than 650° C.

The reaction chamber may be maintained at a pressure in a range of 0.05 Torr to 10 Torr during the provision of the reaction gas and the reaction chamber may comprise a multi-hole gas injector and the reaction gas is provided to the reaction chamber through the multi-hole gas injector. The reaction gases e.g. the precursors may be mixed in the injector to increase the speed of the deposition process. The speed of the deposition process may further be increased when the pressure is increased.

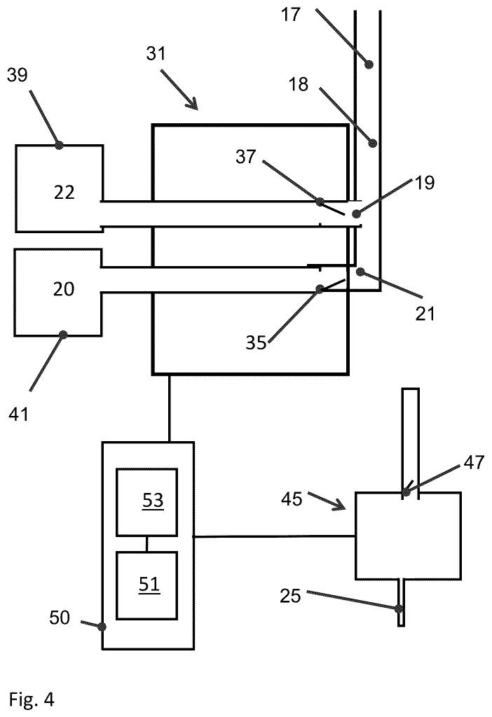

FIG. 4 discloses schematically a valve system 31 for cooperation with the chemical vapor deposition furnace of FIG. 1. FIG. 4 shows that the feed end 18 of the injector 17 (only partially shown) may be connected to a second source 39 comprising a nitrogen precursor 22 via the first feed line 19 and a second valve 37. The feed end 18 of the injector 17 may also being connected to a first source 41 comprising a silicon precursor 20 via the second feed line 21 and a second valve 35. If both the first and second valves 35, 37 are opened for silicon precursor 20 and nitrogen precursor 22 the feed end 18 of the injector 17 will receive a mixed process gas for depositing silicon nitride layers in the reaction chamber 1. It may be understood that with a source is meant a vessel containing the precursor and/or gas or a connection of the fab providing the precursor and/or gas.

A controller 50 may be provided which is operably connected to the valve system 31. The controller 50 may control the first and second valve 35, 37 during deposition. The controller 50 may be provided with a memory 51 and a processor 53. The controller 50 may be provided with a clock, for example as part of the processor 53 to run a recipe as a function of time. The controller 50 may control the flow of reaction gas through the 17 into the reaction chamber 1 to between 100 and 500, preferably 250 cubic centimeters per minute (SCCM).

Returning to FIG. 1, the multi-hole injector 17 may be provided with a plurality of vertically spaced gas injection holes 23 to provide gas received in the interior of the injector 17 at the feed end 18 to the reaction chamber 1 uniformly over the length of the wafer boat 6. The plurality of gas injection holes 23 may extend over a part of a height of the injector 17. The first and second feed line 19, 21 may be provided partially as a passage through one of the flanges 3 and further as a tube to a source of the nitrogen precursor 22 or the silicon precursor 20.

The plurality of gas injection holes may extend over a part of a height of the injector 17. The gas injection holes 23 each may have a gas injection hole diameter of at least about 1 mm. The diameter of the gas injection holes may for example be about 3 mm. All gas injection hole diameters of the injector 17 may be substantially equal. Each gas injection hole may have a gas injection hole area, wherein an aggregate area of all the gas injection hole areas of the injector 17 may be at least about 30 mm². The aggregate area of all the gas injection hole areas may be between about 200 mm² and 400 mm².

The semiconductor processing system may be provided with a purge gas injection system 45 constructed and arranged to provide a purge gas 25 into the reaction chamber 1 near a lower end of the reaction chamber 1. It has been found that by providing the flow of purge gas 25 into the reaction chamber near a lower end the uniformity of quality of the silicon nitride depositions on the substrates over the height over the wafer boat 6 may be improved. The plurality of gas injection holes 23 may extend over a part of a height of the injector 17 and the purge gas injection system 45 may be constructed and arranged to provide the purge gas via purge gas line 24 below the lowest gas injection hole.

The reaction chamber 1 may be supported on a flange 3 with a central inlet opening 10 that is provided with a door 5 which may define an end of the processing chamber 4. The purge gas injection system 45 may be constructed and arranged to provide the purge gas 25 above the door 5. The purge gas injection system 45 may be constructed and arranged to provide the purge gas 25 at the height of the flange 3. The purge gas may be provided through a passage in the flange 3.

The semiconductor processing system may be provided with a gas exhaust opening 8 below the reaction chamber 1 and the purge gas injection system 45 may be constructed and arranged to provide the purge gas 25 at the height of the gas exhaust opening 8.

The purge gas injection system 45 may be constructed and arranged to provide the purge gas 25 into the reaction chamber 1 near the flange 3. A purge gas line 24 provided to the purge gas injection system 45 may therefore be provided partially as a passage through one of the flanges 3 and further as a tube to a source of the purge gas 25.

More details of the purge gas injection system 45 may be shown in FIG. 2. The purge gas injection gas system 45 may be constructed and arranged to provide an inert gas as a purge gas. The purge gas injection system 45 may be constructed and arranged to provide nitrogen as the inert purge gas. Nitrogen is a cheap inert gas which is readily available in a fab. It must be understood that the nitrogen precursor may not be nitrogen. The nitrogen precursor may be reactive while the nitrogen may not be reactive.

The purge gas injection system 45 may be provided with a purge valve 47 to control the flow of purge gas 25. The purge gas injection system 45 may be controlled by the controller 50. The purge gas injection system 45 may be controlled to provide between 0.5 to 10, preferably 1 to 5 standard liter per minute (slm) of purge gas into the reaction chamber 1. The purge valve 47 of the purge injection gas system 45 may be controlled by the controller 50 to adjust the flow of purge gas in the reaction chamber to adjust the uniformity of the quality of the silicon nitride depositions on the substrates over a height over the wafer boat 6.

The purge gas injection system 45 may optionally be provided with an oxygen precursor source constructed and arranged to provide oxygen-containing gas to the reaction chamber 1. The latter may be useful if silicon oxide is deposited on the substrates W.

The semiconductor processing system may be provided with the gas exhaust opening 8 for removing gas at a lower end of the reaction chamber 1. The gas exhaust opening 8 for removing gas from the reaction chamber 1 may be operationally connected to a pump. The pump may be used to control the pressure in the reaction chamber 1 to a pressure between 0.05 Torr to 10 Torr 20 and 500, more preferably between 50 to 300 and most preferably between 100 and 150 milliTorr.

The semiconductor processing system such as the vertical furnace may be used for depositing a silicon nitride layer on a substrates W by: providing a plurality of substrates in a wafer boat 6 and loading the wafer boat in a substantial vertical direction into a reaction chamber 1 of the furnace; flowing a process gas based on a silicon precursor 20 and a nitrogen precursor 22 into the injector 17 to a plurality of vertically spaced gas injection holes 23 to provide the process gas to the reaction chamber 1 and over the substrates in the wafer boat. A purge gas 25 may be provided into the reaction chamber 1 near a lower end of the reaction chamber 4.

The pressure in the reaction chamber may be controlled to a pressure between 0.05 to 10 Torr, more preferably between 0.5 to 5 Torr and most preferably between 1 and 3 Torr. Increasing the pressure may also increase the deposition speed.

The semiconductor processing system may be provided with a heater to heat the substrates in the wafer boat 6. The vertical furnace may be provided with a temperature measurement system mounted on the flange 3 and extending along an outer surface of the liner 2 towards the top end of the liner to measure a temperature. The temperature measurement system may comprise a beam with a plurality of temperature sensors provided along the length of the beam to measure the temperature at different heights. The measured temperature may be used to control the heater.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

1. A semiconductor processing system configured to form a silicon comprising layer on a plurality of substrates, the system comprising:
a reaction chamber constructed and arranged to receive a boat with a plurality of substrates,
a heater configured to heat the reaction chamber to a process temperature,
a silicon precursor source constructed and arranged to provide to the reaction chamber a halosilane having a formula SiH₃₋ₙXₙ—(SiH_{2-q}X_{q})ₚ SiH₃₋ₘXₘ, wherein n and m are independently selected from an integer having a value of at least 0 to at most 3, p is an integer from at least 0 to at most 2, q is an integer from at least 0 to at most 2, X is a halogen and n+m+q has a value of at least 1 to at most 5+q*p.

2. The semiconductor processing system according to claim 1, wherein the halosilane comprises at least 2 halogen atoms and n+m+q has a value of at least 2.

3. The semiconductor processing system according to claim 1, wherein the halosilane in the silicon precursor source comprises chlorine.

4. The semiconductor processing system according to claim 1, wherein the halosilane in the silicon precursor source comprises 1,1-dichlorodisilane or 1,2-dichlorodisilane.

5. The semiconductor processing system according to claim 1, further comprising a nitrogen precursor source constructed and arranged to provide nitrogen-containing gas to the reaction chamber to form silicon nitride.

6. The semiconductor processing system according to claim 5, wherein the nitrogen-containing gas and the halosilane are mixed before being provided to the reaction chamber to form silicon nitride.

7. The semiconductor processing system according to claim 1, wherein the reaction chamber is provided with a liner extending in an interior of the reaction chamber.

8. The semiconductor processing system according to claim 1, wherein the reaction chamber comprises a gas injector to provide a reaction gas comprising the halosilane in the reaction chamber.

9. The semiconductor processing system according to claim 8, wherein the gas injector is a multi-hole gas injector.

10. The semiconductor processing system according to claim 1, further comprising an oxygen precursor source constructed and arranged to provide oxygen-containing gas to the reaction chamber.

11. A semiconductor precursor storage vessel constructed and arranged for providing a precursor to a vertical furnace and comprising a halosilane having a formula SiH₃₋ₙXₙ—(SiH_{2-q}X_{q})ₚ SiH₃₋ₘXₘ, wherein n and m are independently selected from an integer having a value of at least 0 to at most 3, p is an integer having a value from at least 0 to at most 2, q is an integer having a value from at least 0 to at most 2, X is a halogen and n+m+q has a value of at least 1 to at most 5+q*p.

12. A method of forming a silicon comprising layer on a plurality of substrates, the method comprising:
providing a boat with the plurality of substrates to a reaction chamber,
providing a silicon precursor comprising a halosilane to the reaction chamber to form the silicon comprising layer on the plurality of substrates, wherein the halosilane has a formula SiH₃₋ₙXₙ—(SiH_{2-q}X_{q})ₚ SiH₃₋ₘXₘ, wherein n and m are independently selected from an integer having a value of at least 0 to at most 3, p is an integer having a value from at least 0 to at most 2, q is an integer having a value from at least 0 to at most 2, X is a halogen and n+m+q has a value of at least 1 to at most 5+q*p.

13. The method according to claim 12, wherein the halosilane comprises at least 2 halogen atoms so that n+m+q has a value of at least 2 and the halogen comprises chlorine.

14. The method according to claim 12, wherein the halosilane comprises 1,1-dichlorodisilane or 1,2-dichlorodisilane.

15. The method according to claim 12, wherein the method further comprises providing a nitrogen precursor or an oxygen precursor to the reaction chamber substantially simultaneously.

16. The method according to claim 15, wherein the method comprises mixing the nitrogen precursor or the oxygen precursor with the halosilane before being provided to the reaction chamber.

17. The method according to claim 12, wherein the method further comprises providing a nitrogen precursor or an oxygen precursor alternatingly to the reaction chamber.

18. The method according to claim 12, wherein the halosilane is provided to the reaction chamber, at a flow in a range of 0.05 slm to 5 slm.

19. The method according to claim 12, wherein a temperature of the reaction chamber during provision of the halosilane is less than 800° C.

20. The method according to claim 12, wherein the reaction chamber is maintained at a pressure in a range of 0.05 Torr to 10 Torr during provision of the halosilane and the reaction chamber comprises a multi-hole gas injector and a reaction gas is provided to the reaction chamber through the multi-hole gas injector.
